(19) United States
(12) Patent Application Publication
(10) Pub. No.: US 2014/0030048 A1
(43) Pub. Date: Jan. 30, 2014

(54) WORKPIECE TRANSPORT DEVICE

(71) Applicant: EBARA CORPORATION, Tokyo (JP)

(72) Inventors: Ryuichi KOSUGE, Tokyo (JP); Hiroaki NISHIDA, Tokyo (JP); Tadakazu SONE, Tokyo (JP); Hideo AIZAWA, Tokyo (JP); Tomohiro TANAKA, Tokyo (JP)

(73) Assignee: EBARA CORPORATION, Tokyo (JP)

(21) Appl. No.: 13/952,000

(22) Filed: Jul. 26, 2013

(30) Foreign Application Priority Data
Jul. 27, 2012 (JP) 166701/2012
Mar. 6, 2013 (JP) 043948/2013

(51) Int. Cl. H01L 21/677

(52) U.S. Cl. CPC H01L 21/677
USPC 414/225.01

(57) ABSTRACT

A workpiece transport device for transporting a workpiece having a substrate layer and a layer to be processed on a portion of the substrate layer is provided. This workpiece transport device has a workpiece holding mechanism arranged to operate so as to hold and release the workpiece. The workpiece holding mechanism has at least one tapered workpiece holding surface on which the substrate layer of the workpiece is held in a state where the layer to be processed is positioned below the substrate layer. The tapered workpiece holding surface is formed so that a clearance equal to or larger than a predetermined distance R exists between the workpiece holding surface and the layer to be processed of the workpiece when the workpiece is held by the workpiece holding mechanism.

### CROSS REFERENCE TO RELATED APPLICATIONS

This application is based on and claims priority from Japanese Patent Applications No. 2012-166701 filed on Jul. 27, 2012, and No. 2013-43948 filed on Mar. 6, 2013.

### TECHNICAL FIELD

This disclosure relates to a mechanism for holding and transporting a workpiece in an apparatus for processing a workpiece such as a semiconductor wafer.

### BACKGROUND ART

In semiconductor device manufacturing processes, various devices are ordinarily used for transport of workpieces such as semiconductor wafers (see, for example, International Publication No. WO2007/099976). In some cases, semiconductor wafer is bonded on a glass substrate, the semiconductor wafer is transported together with the glass substrate and a treatment such polishing is performed on the semiconductor wafer. In such cases, when the semiconductor wafer is transported, it is desirable to perform transport by holding only the glass substrate so that the transport mechanism does not contact the semiconductor portion to be treated.

In some case of manufacture of a semiconductor device, transport of semiconductor wafers differing in size is required. Since the semiconductor wafer transport mechanism is designed and adjusted according to a size of wafer to be treated, failure to suitably transport wafers may occur if the wafers are not uniform in size. For example, in a case where the size of a semiconductor wafer is smaller than the size for which the transport mechanism is adjusted, the holding force is reduced and a gap at a position at which the wafer is held may become so excessively large so that the wafer positioning accuracy is reduced. Also, in a case where the size of a semiconductor wafer is larger than the size for which the transport mechanism is adjusted, the holding force is excessively large, an excessive stress may be caused in the wafer and failure to suitably hold the wafer may occur.

International Publication No. WO2007/099976 discloses a linear transporter in a chemical mechanical polishing (CMP) apparatus that transports a substrate between a polishing unit that polishes the substrate and a cleaning unit that cleans the substrate after polishing. This linear transporter has a plurality of pins projecting upward from a stage capable of moving linearly and reciprocatingly. Each pin has such a shape as to become smaller in outside diameter toward its upper portion or end. A slant surface slanted with respect to a horizontal direction is formed with such a shape. The linear transporter transports a substrate by moving the transport stage while maintaining the substrate in a state of being placed on the slant surfaces in the region inside the plurality of pins.

It is desirable to design the wafer holding mechanism in the transport mechanism so that, in transporting a semiconductor wafer bonded to an upper surface of a glass substrate, the wafer holding mechanism contacts only the glass substrate and does not contact the semiconductor wafer. However, there is an error in positioning the semiconductor wafer in bonding the semiconductor wafer to the glass substrate, and bonding at the desired position cannot always he performed correctly. If the bonded position of the semiconductor wafer on the glass substrate deviates from the ideal position, there is a possibility of the transport mechanism contacting and damaging the semiconductor wafer when holding the glass substrate, it is, therefore, desirable that the holding mechanism in the transport mechanism be prevented from contacting the semiconductor wafer even when the bonded position of the semiconductor wafer on the glass substrate deviates from the ideal position.

In some case of transport of semiconductor wafers differing in size, the range of movement of a holding mechanism including arms for holding a wafer is changed. However, changing the range of movement of the holding mechanism requires temporarily stopping the manufacturing process and is, therefore, time-consuming it is, therefore, desirable for transport of semiconductor wafers of a variety of sizes to be enabled in advance.

In the above-described linear transporter, the substrate including a wafer is only placed on the slant surfaces of the pins and is not firmly fixed on the pins. Therefore, there is a possibility of the placed position of the substrate being shifted due to acceleration (including negative acceleration) during transport of the substrate, for example, by an impact when the substrate is stopped. When a large shift is caused thereby, that is, one end of the placed substrate is largely shifted upward along the slant surfaces, the other end of the placed substrate is shifted downward. This may result in a fall of the substrate from the transport device. If the substrate falls, the recovery time for again placing the substrate is required and the manufacturing efficiency is reduced. There is also a risk of the substrate being damaged by the fall. This is a common problem with substrate transport devices of the type characterized by transporting a substrate in a placed-on state, not limited to the above-described linear transporter. Under the above-described circumstances, there is a need to reduce the occurrence of falls of substrates in substrate transport devices. Transport of a substrate at a low speed, as a prevention against the occurrence of large acceleration, is conceivable as a measure to reduce the occurrence of falls of substrates. Such a measure increases the time required for transport, resulting in a reduction in manufacturing efficiency.

### SUMMARY OF INVENTION

The present invention solves at least part of the above-described problem.

According to a first aspect of the present invention, there is provided a workpiece transport device for transporting a workpiece having a substrate layer and a layer to be processed, such as polishing, on a portion of the substrate layer. This workpiece transport device has a workpiece holding mechanism arranged to operate so as to hold and release the workpiece. The workpiece holding mechanism has at least one slanted workpiece holding surface on which the substrate layer of the workpiece is held in a state where the layer to be processed is positioned below the substrate layer. The slanted workpiece holding surface is formed so that a clearance equal to or larger than a predetermined distance R exists between the workpiece holding surface and the layer to be processed of the workpiece when the workpiece is held by the workpiece holding mechanism.

According to a second aspect of the present invention, in the first aspect, the slope angle θb of the slanted workpiece holding surface satisfies θ3≦θb≦90° and θ3=θ1+θ2. A straight line tangent to the substrate layer and the layer to be processed is assumed to be L1; the angle between the straight line L1 and the substrate layer is assumed to be θ1; when a circle with a radius R centered at the point at which the straight line L1 is tangent to the layer to be processed is drawn, a straight line tangent to the circle with radius R and the substrate layer is assumed to be L2; the angle between the straight line L1 and the straight line L2 is assumed to be θ2; and the angle formed by the straight line L2 and a straight line parallel to a surface of the layer to be processed is assumed to be θ3.

According to a third aspect of the present invention, in the first or second aspect, the workpiece holding surface has a first surface for holding a workpiece of a first size and a second surface for holding a workpiece of a second size.

According to a fourth aspect of the present invention, a workpiece holding surface has a first surface for holding a workpiece of a first size and a second surface for holding a workpiece of a second size.

According to a fifth aspect of the present invention, there is provided a workpiece polishing apparatus including the workpiece transport device according to the first fourth aspect of the present invention.

According to a sixth aspect of the present invention, there is provided a substrate transport device for transporting a substrate. This substrate transport device includes a transport stage arranged to be movable in a horizontal direction, and three or more substrate placement parts provided so as to project upward from the transport stage along a vertical direction. Each of the substrate placement parts includes a first slant surface slanted with respect to the horizontal direction, facing upward and provided for placement of the substrate inside the three or more substrate placement parts, and a second slant surface slanted with respect to the horizontal direction, facing downward, and formed above the first slant surface.

In this substrate transport device, even if one end of the substrate is shifted upward along the first slant surface of one of the substrate placement parts when the substrate is transported by being placed on the substrate placement parts, this one end is brought into abutment against the second slant surface, so that this one end does not further move upward. As a result, the other end of the substrate does not fall from the first slant surfaces of the other substrate placement parts. That is, the occurrence of falls of substrates can be reduced.

According to a seventh aspect of the present invention, in the sixth aspect, the second slant surface may he formed in such a position as to continue to the first slant surface. According to this aspect, the range of upward shifting of the substrate can be limited in comparison with a case where a surface extending along a direction perpendicular to the horizontal direction exists between the first slant surface and the second slant surface. As a result, the occurrence of falls of substrates can he further reduced.

According to an eighth aspect of the present invention, in the sixth or seventh aspect, the lower end of the first slant surface may be positioned on the side on which the substrate is placed relative to the upper end of the second slant surface along the direction of a straight line passing through centers of arbitrary two of the three or more substrate placement parts. According to this aspect, the substrate can be placed on the first slant surface from above while being held in a state of being parallel to the horizontal direction without interfering with the upper end of the second slant surface. That is, there is no need to incline the substrate with respect to the horizontal direction. As a result, the operability relating to transport of the substrate is improved.

According to a ninth aspect of the present invention, in any one of the sixth to eighth aspects, the first slant surface may include a third slant surface having a first slope angle with respect to the horizontal direction, and a fourth slant surface formed higher than the third slant surface and having a second slope angle larger than the first slope angle. According to this aspect, a substrate differing in size can be placed on any one of the third slant surface and the fourth slant surface. That is, one substrate transport device can handle a plurality of substrates differing in size, and the device is thus improved in versatility.

According to a tenth aspect of the present invention, there is provided a substrate polishing apparatus including the substrate transport device according to any one of the sixth to ninth aspects. This substrate polishing apparatus has the same advantage as that in the sixth to ninth aspects.

### BRIEF DESCRIPTION OF DRAWINGS

FIG. 1 is a plan view showing the entire construction of an illustrative example of a polishing apparatus;

FIG. 2 is a perspective view showing an outline of the polishing apparatus shown in FIG. 1;

FIG. 3 is a perspective view showing an illustrative example of a swing transporter;

FIG. 4a is a top view showing holding parts of the swing transporter shown in FIG. 3;

FIG. 4b is a side view showing the holding parts of the swing transporter shown in FIG. 3;

FIG. 4c is an enlarged side view of a contact piece of the holding parts of the swing transporter shown in FIG. 3;

FIG. 5 is a front view of an illustrative example of a linear transport;

FIG. 6 is a plan view of the linear transporter shown in FIG. 5;

FIG. 7a is a top view of a transport stage of the linear transporter shown in FIG. 5;

FIG. 7b is a side view of the transport stage of the linear transporter shown in FIG. 5;

FIG. 7c is an enlarged side view of a pin according to one embodiment of the transport stage of the linear transporter shown in FIG. 5;

FIG. 7d is a diagram showing the construction of pin (substrate placement part) according to another embodiment usable for the transport stage of the linear transporter shown in FIG. 5;

FIG. 7e is a diagram showing a state where the occurrence of falls of substrates is reduced;

FIG. 7f is a diagram showing a state where a substrate falls from a substrate transport device as a comparative example;

FIG. 8 is a perspective view showing an illustrative example of an inverter;

FIG. 9 is a plan view of the inverter shown in FIG. 8;

FIG. 10 is a side view of the inverter shown in FIG. 8;

FIG. 11 is a longitudinal sectional view showing an opening/closing mechanism of the inverter shown in FIG. 8;

FIG. 12 is a longitudinal sectional view showing the opening/closing mechanism of the inverter shown in FIG. 8, and showing a state where a wafer is released;

FIG. 13a is a side view of a chuck of the inverter shown in FIG. 8, showing a state before a wafer is inverted;

FIG. 13b is a side view of the chuck of the inverter shown in FIG. 8, showing a state after the wafer is inverted;

FIG. 14 is a diagram for explaining a method of determining a slope angle θb of the slant surface of the chuck of the inverter shown in FIG. 8;

FIG. 15 is a longitudinal sectional view of an illustrative example of a lifter;

FIG. 16a is a top view showing a stage of the lifter shown in FIG. 15;

FIG. 16b is a side view showing the stage of the lifter shown in FIG. 15;

FIG. 16c is an enlarged partial side view showing a claw of the stage of the lifter shown in FIG. 15;

FIG. 17 is a perspective view showing an illustrative example of a transport unit in a cleaning section 4;

FIG. 18a is a perspective view showing a chuck contact piece in a single state of the transport unit shown in FIG. 17;

FIG. 18b is top view of the chuck contact piece shown in FIG. 18; and

FIG. 18c is a sectional view of the chuck contact piece shown in FIG. 18, taken along line B-B.

### DESCRIPTION OF EMBODIMENTS

Embodiments of the present invention will be described with reference to the accompanying drawings. A semiconductor wafer polishing apparatus similar to the one disclosed in International Publication No. WO2007/099976 is taken as an example. Components identical or corresponding to each other are indicated by the same reference characters in the accompanying drawings, and redundancy of descriptions of them is avoided. In the polishing apparatus described below, a well-known arrangement or an arrangement disclosed in International Publication No. WO2007/099976 can be adopted for a component of the polishing apparatus described below other than the structure of wafer holding mechanisms in wafer transport devices. Therefore, detailed descriptions for it will not be made.

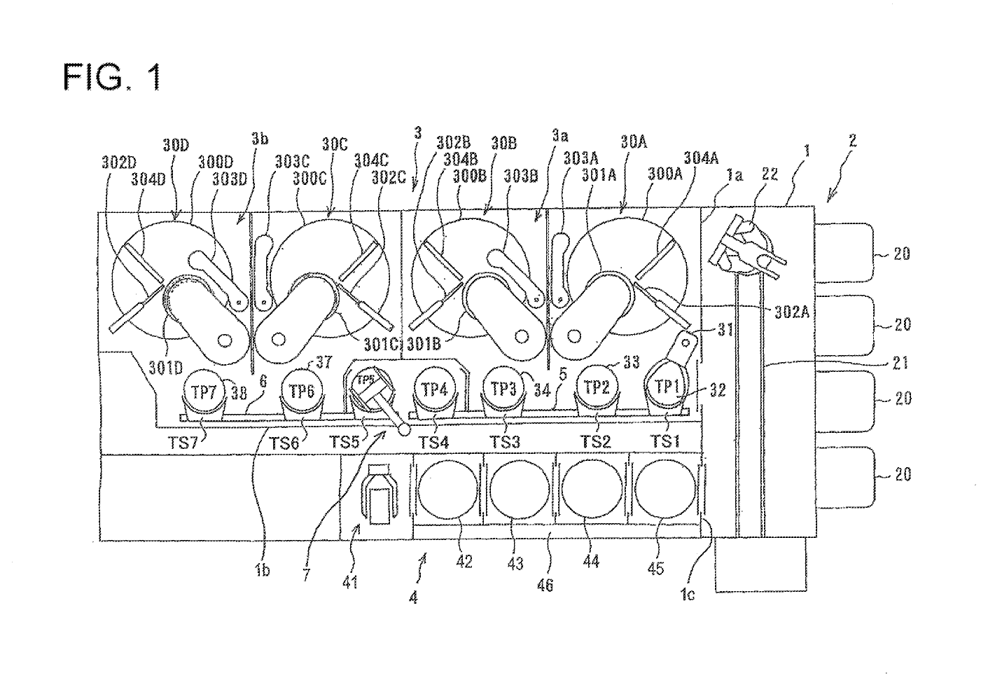

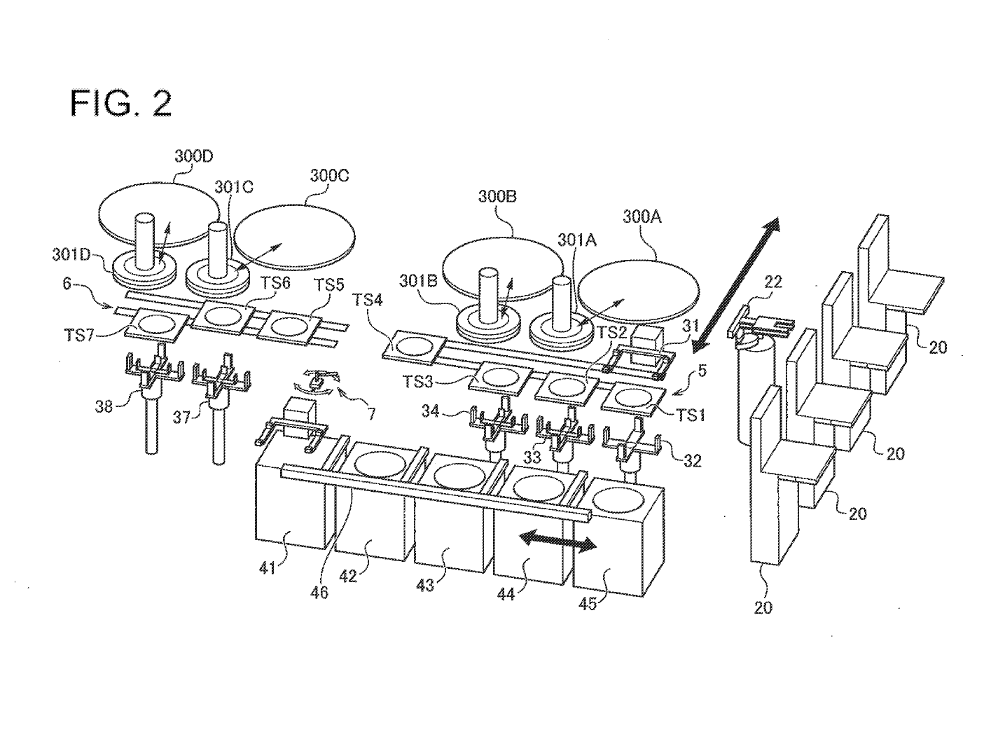

FIG. 1 is a plan view showing the entire construction of an illustrative example of the polishing apparatus. FIG. 2 is a perspective view showing an outline of the polishing apparatus shown in FIG. 1. As shown in FIG. 1, the polishing apparatus is provided with a generally rectangular housing 1. The interior of the housing 1 is partitioned into a loading /unloading section 2, polishing sections 3 (3a, 3b) and a cleaning section 4 by partition walls 1a, 1b, and 1c. Each of the loading/unloading section 2, the polishing sections 3a and 3b and the cleaning section 4 is independently assembled and is independently exhausted.

The loading/unloading section has two or more (four in the present embodiment) front loading portions 20 on which wafer cassettes in which a multiplicity of semiconductor wafers are stocked are placed, and which are arranged adjacent to each other along the width direction of the polishing apparatus (a direction perpendicular to the lengthwise direction). On each front loading portion 20, an open cassette, a Standard Manufacturing Interface (SMIF) pod, or a Front Opening Unified Pod (FOUP) can be mounted. Each of the SMIF and the FOUP is a hermetically sealed container in which a wafer cassette is housed and covered with a partition wall to be maintained in an environment independent of the external space.

The poliching section 3 is a region where polishing is performed on semiconductor wafers. The polishing section 3 includes a first polishing section 3a having a first polishing unit 30A and a second polishing unit 30B provided therein, and a second polishing section 3b having a third polishing unit 30C and a fourth polishing unit 30D provided therein. The first polishing unit 30A, the second polishing unit 30B, the third polishing unit 300 and the fourth polishing unit 30D are arranged along the lengthwise direction of the apparatus, as shown in FIG. 1.

As shown in FIG. 1, the first polishing unit 30A is provided with a polishing table 300A having a polishing surface, a top ring 301A for polishing a semiconductor wafer while holding the semiconductor wafer and pressing the semiconductor wafer against the polishing table 300A, a polishing liquid supply nozzle 302A for supplying a polishing liquid and a dressing liquid (e.g., water) to the polishing table 300A, a dresser 303A for dressing the polishing table 300A, and an atomizer 304A for atomizing a mixture fluid formed of a liquid (e.g., pure water) and a gas (e.g., nitrogen) or a liquid (e.g., pure water) and jetting the atomized fluid or liquid from one or a plurality of nozzles to the polishing surface. Similarly, the second polishing unit 30B is provided with a polishing table 300B, a top ring 301B, a polishing liquid supply nozzle 302B, a dresser 303B, and an atomizer 304B. The third polishing unit 300 includes a polishing table 3000, a top ring 301C, a polishing liquid supply nozzle 302C, a dresser 303C, and an atomizer 304C. The fourth polishing unit 30D includes a polishing table 300D, a top ring 301D, a polishing liquid supply nozzle 302D, a dresser 303D, and an atomizer 304D.

Between the first polishing unit 30A and the second polishing unit 30B in the first polishing section 3a and the cleaning section 4, a first linear transporter 5 is disposed that transports a wafer between four transport positions (assumed to be a first transport position TP1, a second transport position TP2, a third transport position TP3 and a fourth transport position TP4 in order from the loading/unloading section 2 side) along the lengthwise direction. Above the first transport position TP1 of the first linear transporter 5, an inverter 31 that inverts a wafer received from a transfer robot 22 in the loading/unloading section 2 is disposed. Below the first transport position TP1, a lifter 32 capable of moving upward and downward is disposed. Below the second transport position TP2, a pusher 33 capable of moving upward and downward is disposed. Below the third transport position TP3, a pusher 34 capable of moving upward and downward is disposed. A shutter 12 is provided between the third transport position TP3 and the fourth transport position TP4.

In the second polishing section 3b, a second linear transporter 6 that transports a wafer between three transport positions (assumed to be a fifth transport position TP5, a sixth transport position TP6 and seventh transport position TP7 in order from the loading/unloading section 2 side) along the lengthwise direction is disposed adjacent to the first linear transporter 5. A pusher 37 is disposed below the sixth transport position TP6 of the second linear transporter 6. A pusher 38 is disposed below the seventh transport position TP7. A shutter 13 is provided between the fifth transport position TP5 and the sixth transport position TP6.

The cleaning section 4 is a region where a polished semiconductor wafer is cleaned. The cleaning section 4 is provided with an inverter 41 that inverts a wafer, four cleaners 42 to 45 that clean a polished semiconductor wafer, and a transport unit 4G that transports a wafer between the inverter 41 and the cleaners 42 to 45. The inverter 41 and the cleaners 42 to 45 are arranged in a straight row along the lengthwise direction. A filter fan unit with a clean air filter (not illustrated) is provided above the cleaners 42 to 45. Clean air produced by the filter fan unit removing particles is blown downward at all times. The interior of the cleaning section 4 is always maintained at a pressure higher than the pressure in the polishing section 3 in order to prevent particles from flowing thereinto from the polishing section 3.

As shown in FIG. 1, a swing transporter (wafer transport mechanism) 7 that transports a wafer between the first linear transporter 5, the second linear transporter 6 and the inverter 41 in the cleaning section 4 is disposed between the first linear transporter 5 and the second linear transporter 6. The swing transporter 7 can transport a wafer from the fourth transport position TP4 of the first linear transporter 5 to the fifth transport position TP5 of the second linear transporter 6, transport a wafer from the fifth transport position TP5 of the second linear transporter 6 to the inverter 41 and transport a wafer from the fourth transport position. TP4 of the first linear transporter 5 to the inverter 41.

Each transport mechanism will be described below.

Swing Transporter

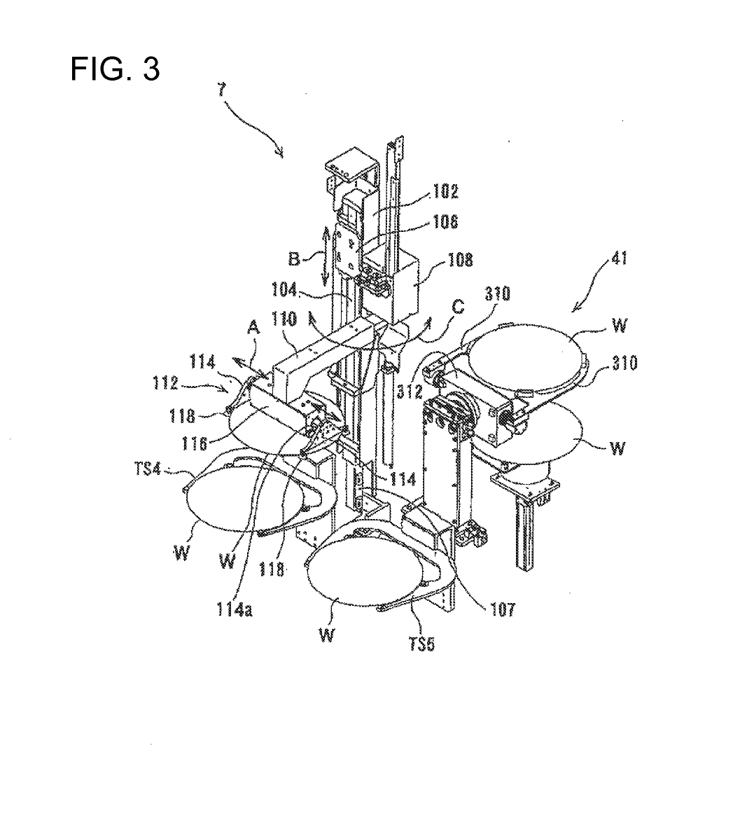

The swing transporter 7 will be described. FIG. 3 is a perspective view showing the swing transporter 7 together with the inverter 41 in the cleaning section 4. As shown in FIG. 3, the swing transporter 7 in the present embodiment is mounted on a frame 102 of a box-like member in the first polishing section 3a, and is provided with a robot cylinder 104 disposed in the frame 102 extending vertically and generally U-shaped in section, a base bracket 106 that moves upward and downward on the robot cylinder 104, a motor 107 that causes the robot cylinder 104 to more upward and downward, a motor cover 108 attached to the base bracket 106, a turnable arm 110 attached to a rotating shaft of a motor housed in the motor cover 108, and a wafer holding mechanism 112 attached to a distal end of the turnable arm 110.

The wafer holding mechanism 112 is provided with a pair of holding parts 114 that hold peripheral edges of wafer W from opposite sides and an opening/closing mechanism 116 that opens or closes rods 114a of the holding parts along a diametric direction (the direction of arrow A) of wafer W. The pair of holding parts 114 are disposed so as to face each other from positions on opposite sides of a center of wafer W, and two pairs of contact pieces (chuck mechanism) 118 that contact outer peripheral portions of wafer W in a point contact manner are respectively provided on opposite ends of the holding parts 114. The contact pieces 118 are provided so as to project downward from the opposite ends of the holding parts 114.

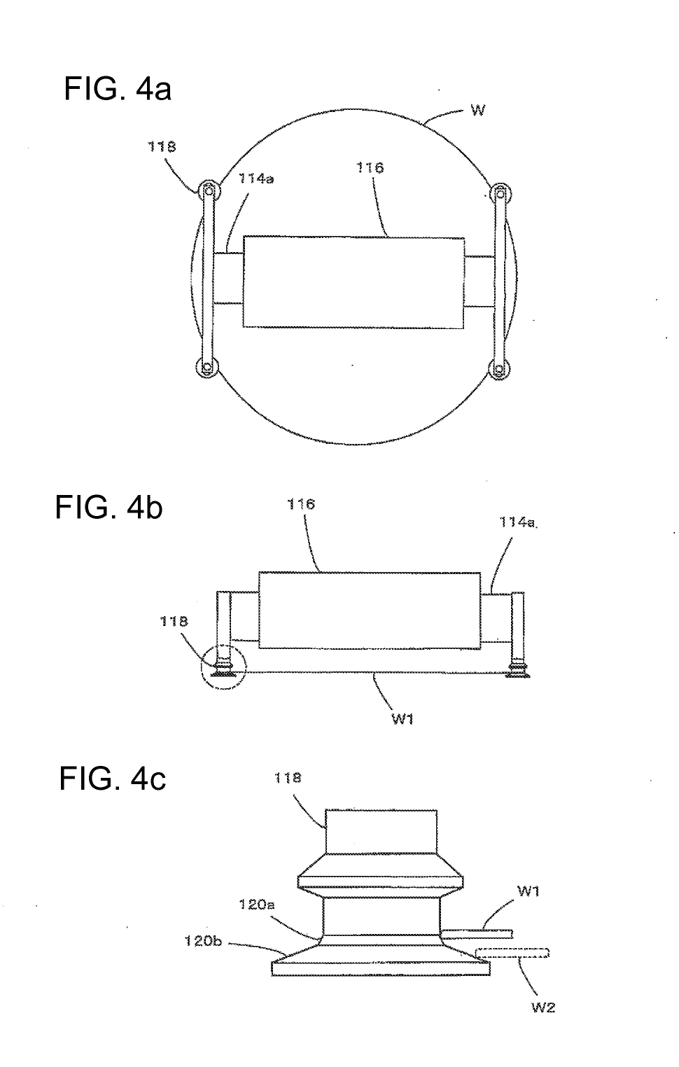

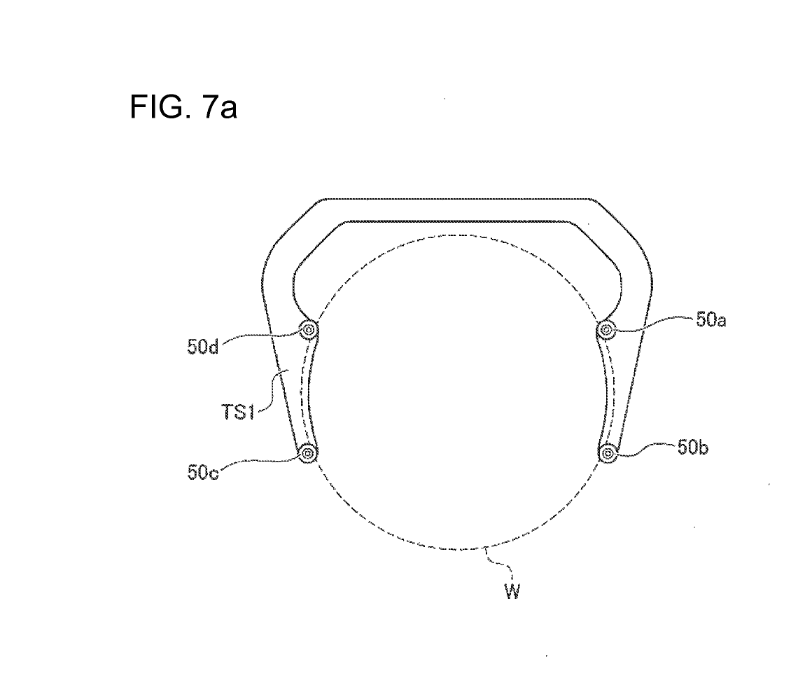

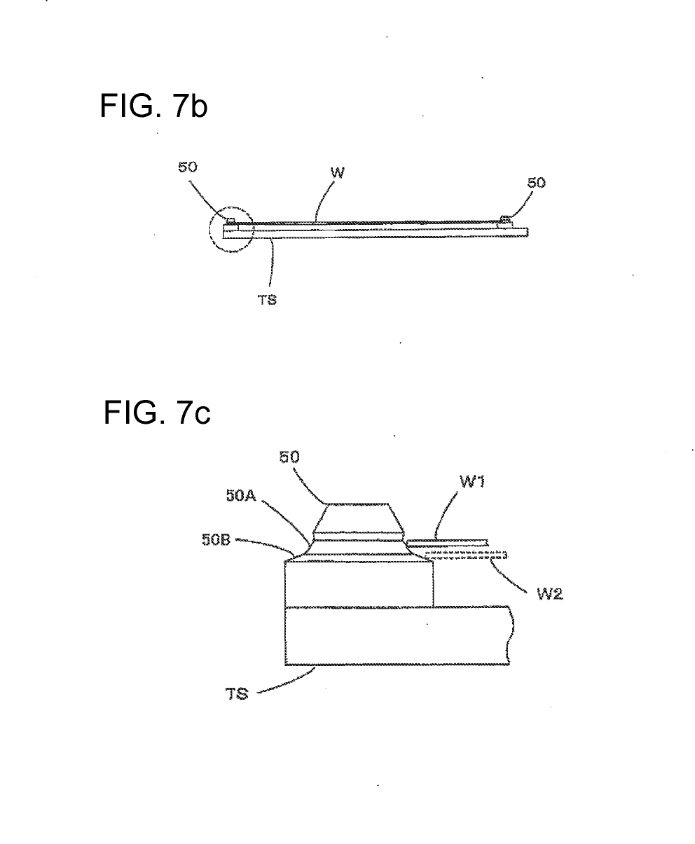

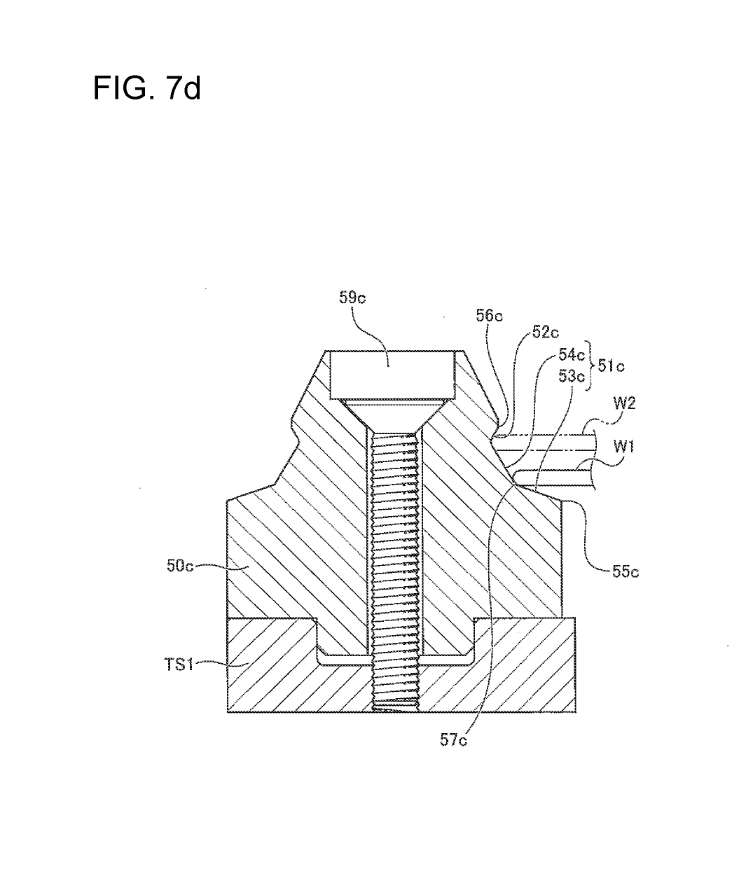

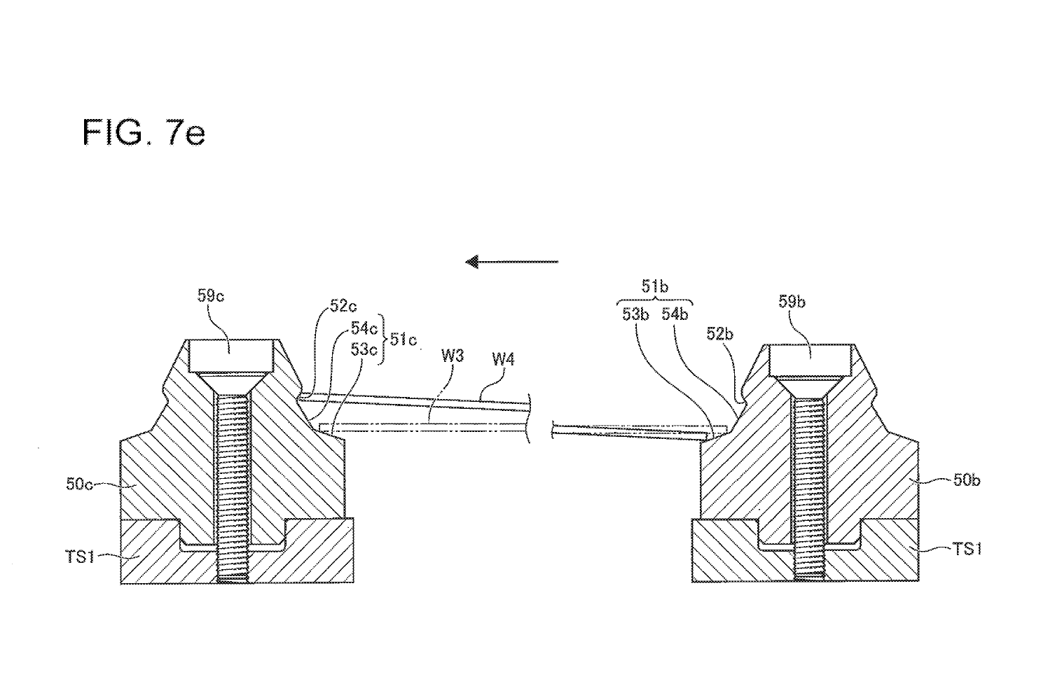

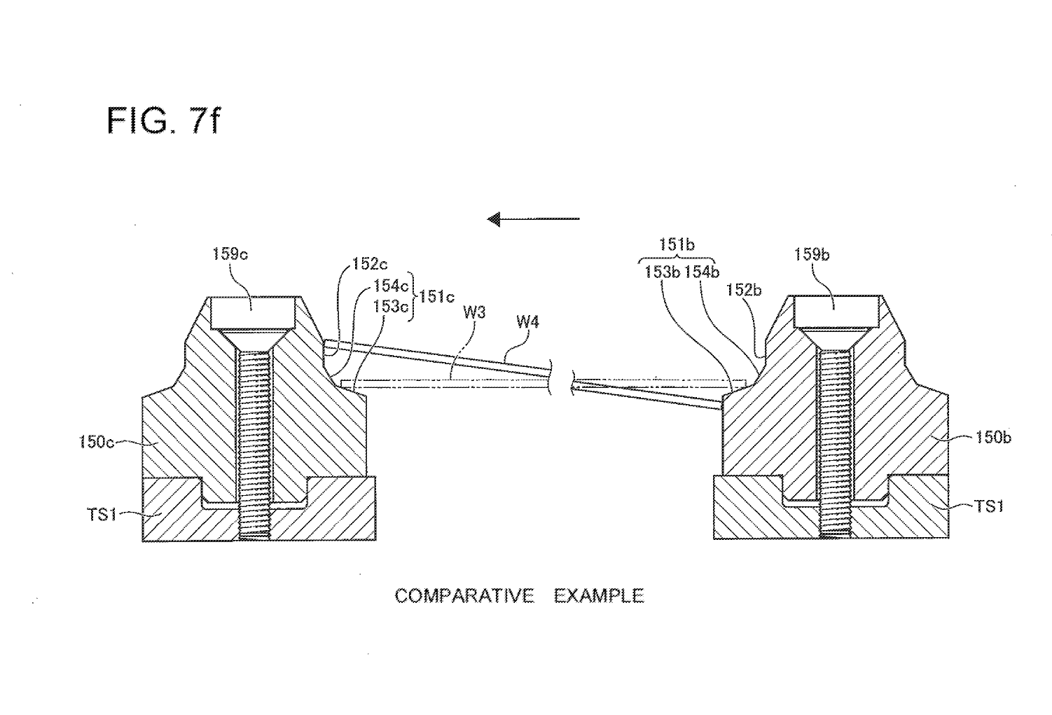

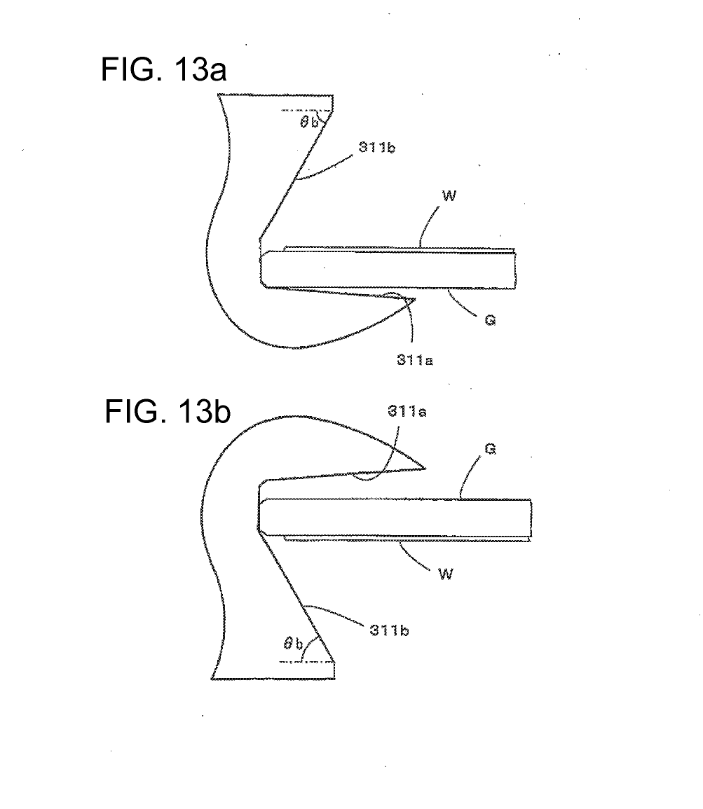

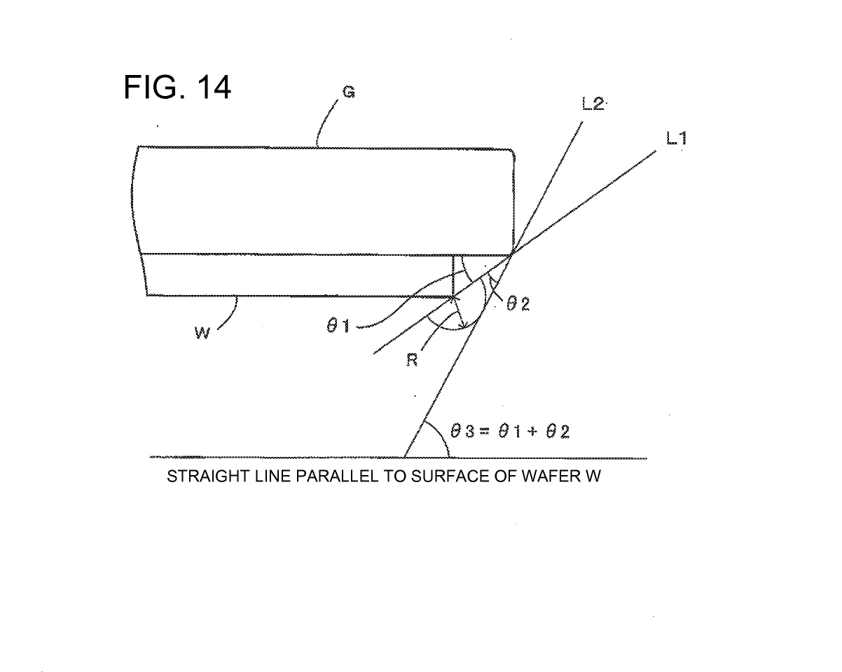

The opening/closing mechanism 116 is constituted by an air cylinder, for example. The opening/closing mechanism 116 moves the holding parts 114 in such directions that the holding parts 114 are brought closer to each other, thereby holding wafer W. The opening/closing mechanism 116 moves the holding parts 114 in such directions that the holding parts 114 move away from each other, thereby releasing wafer W. FIG. 4 comprises diagrams showing the holding parts 114. FIG. 4(a) is a top view of the holding parts 114; FIG. 4(b) is a side view of the holding parts 114; and FIG. 4(c) is an enlarged side view of the contact piece 118. In FIG. 4, illustration of structures other than the holding parts is omitted for clarification of illustration and description. As shown in FIG. 4(c), tapered portions 120a and 120b differing in slope angle from each other are formed in the contact piece 118, and each of workpieces differing in size (for example, wafers W1, W2 shown in FIGS. 7c and 7d; and a glass substrate G having a semiconductor wafer W shown in FIGS. 13 and 14) can be supported on the corresponding one of the tapered portions 120a and 120b. Therefore the swing transporter 7 in the thus-arranged embodiment can transport wafers differing in size. In the description of the present embodiment, an example of the provision of two contact pieces 118 on each of the holding parts 114 has been described. However, the present invention is not limited to this. Three or more contact pieces 118 may be provided on each of the holding parts 114.

The wafer holding mechanism. 112 of the swing transporter 7 in the present embodiment holds and releases wafer W by oppositely moving the pair of holding parts 114 along one direction and can therefore hold wafer W with reliability.

A ball screw and a slide guide are provided in the robot cylinder 104, and the base bracket 106 on the robot cylinder 104 is moved upward or downward by driving with the motor 107 (arrow B). The wafer holding mechanism 112 is thereby moved upward and downward with the base bracket 106. Thus, the robot cylinder 104 and the base bracket 106 constitute an upward/downward movement mechanism for moving the wafer holding mechanism 112 along the frame 102.

The turnable arm 110 is swung on the rotating shaft of the motor in the motor cover 109 by driving with the motor (arrow C). The wafer holding mechanism 112 is thereby moved between the first linear transporter 5, the second linear transporter 6 and the inverter 41 in the cleaning section 4. A turn mechanism for turning the wafer holding mechanism 112 on the rotating shaft of the motor 108 adjacent to the frame 102 is constituted by the motor in the motor cover 108 and the turnable arm 110. In the description of the present embodiment, an example of turning the wafer holding mechanism 112 on the rotating shaft of the motor in the motor cover 108 adjacent to the frame 102 has been described. However, the present invention is not limited to this. The wafer holding mechanism 112 may he turned on the frame 102.

To hold wafer W, the base bracket 106 is moved downward until the contact pieces 118 of the holding parts 114 are positioned below wafer W while the holding parts 114 is in an open state. The opening/closing mechanism 116 is then driven to move the holding parts 114 in such directions that the holding parts 114 are brought closer to each other, thereby positioning innermost peripheral portions of the contact pieces 118 inside the outermost peripheral end of wafer W. In this state, the base bracket 106 is moved upward to lift wafer W in the state of being held on the contact pieces 118 of the holding parts 114 in the present embodiment, the contact pieces 118 and wafer W are brought into point contact with each other and the area of contact of wafer W can be minimized, so that dust attached to the surface of wafer W when the wafer is held can be reduced.

Linear Transporter

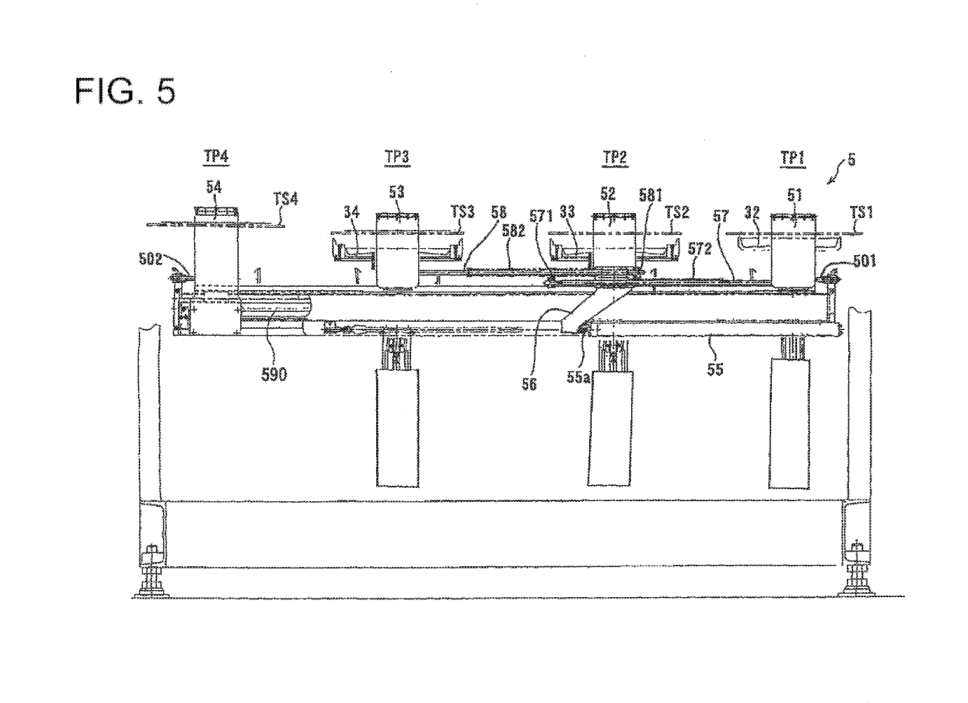

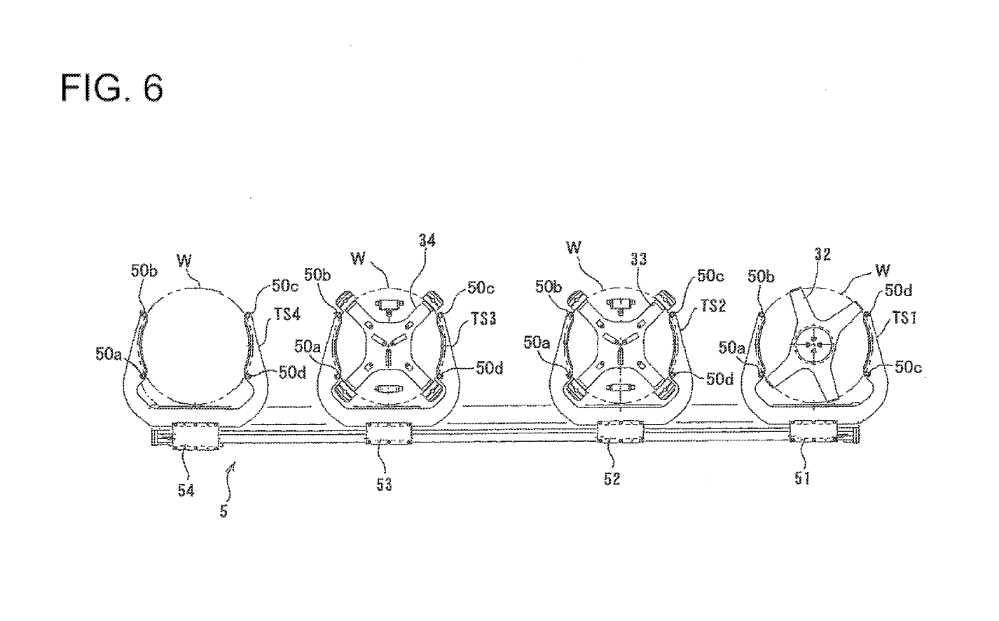

Next, the first linear transporter 5 in the first polishing section 3a will be described. FIG. 5 is a front view of the first linear transporter 5, and FIG. 6 is a plan view of FIG. 5. As shown in FIGS. 5 and 6, the first linear transporter 5 is provided with four transport stages TS1, TS2, TS3, and TS4 capable of moving linearly and reciprocatingly, and these stages are constructed in two upper and lower strata. That is, the first transport stage TS1, the second transport stage TS2 and the third transport stage TS3 are disposed in the lower stratum, and the fourth transport stage TS4 is disposed in the upper stratum.

The transport stages TS1, TS2, and TS3 in the lower stratum and the transport stage TS4 in the upper stratum move on the same axis as viewed in the plan view of FIG. 6. However, because of the disposition at different heights, the transport stages TS1, TS2, and TS3 in the lower stratum and the transport stage TS4 in the upper stratum can move freely without interfering with each other. The first transport stage TS1 transports a wafer between the first transport position TP1, at which the inverter 31 and the lifter 32 are disposed, and the second transport position TP2, at which the pusher 33 is disposed (which is a wafer delivery position) the second transport stage TS2 transports a wafer between the second transport position TP2 and the third transport position TP3, at which the pusher 34 is disposed (which is a wafer delivery position); and the third transport stage TS3 transports a wafer between the third transport position TP3 and the fourth transport position TP4. The fourth transport stage TS4 delivers a wafer between the first transport position TP1 and the fourth transport position TP4.

As shown in FIG. 6, each of the transport stages TS1, TS2, TS3, and TS4 has, as four substrate mount portions, pins 50a to 50d are fixed on its upper surface wafer is supported on the transport stage by being placed on slant surfaces (described later in detail) formed on the pins 50a to 50d, with the outer peripheral edges of the wafer guided and positioned thereby. The number of pins is not limited to four. Any number of pins not smaller than three may be provided. These pins 50a to 50d are formed of a resin such as polypropylene (PP), polychlorofluoroethylene (POTFE) or polyetheretherketone (PEEK). A sensor (not shown) that detects the presence/absence of a wafer by means of a transmission-type sensor is arranged on each transport stage to enable detection of whether or not a wafer exists on the transport stage.

Placement of a wafer on the pins 50a to 50d is performed by the lifter 32. First, the lifter 32 disposed lower than the transport stages TS1 to TS4 passes through the internal space of one of the transport stages TS1 to TS4 (assumed here to be the first transport stage TS1) (the configuration of which is described later) and moves upward to a position immediately below a wafer held in a clamping manner by the inverter 31 (see FIG. 1) disposed above. Next, the inverter 31 opens the clamp to place the wafer un the lifter 32. The lifter 32 moves downward and passes through the internal space of the first transport stage TS1 with the wafer placed thereon. By this passing operation, the wafer placed. on the lifter 32 is removed from the lifter 32 and placed on the pins 50a to 50d disposed outside the lifter 32. The pusher 33, whose operation not described in detail, delivers to the top ring 301A a wafer placed on the first transport stage TS1 by using the same principle as that used by the lifter 32, which operation will not be described in detail. The pusher 33 also delivers to the second transport stage TS2 a wafer polished by the first polishing unit 30A. Similarly, the pusher 34 delivers to the top ring 301B a wafer placed on the second transport stage TS2, and delivers to the third transport stage TS3 a wafer polished by the second polishing unit 30B.

The transport stages TS1 to TS4 are respectively supported by supporting portions 51, 52, 53, and 54. As shown in FIG. 5, a connecting member 56 connected to a rod 55a of an air cylinder (drive mechanism) 55 is attached to a lower portion of the supporting portion 52 for the second transport stage TS2 (driving-side transport stage). A shaft 57 and a shaft 58 are passed through the supporting portion 52 for the second transport stage TS2. One end of the shaft 57 is connected to the supporting portion 51 for the first transport stage TS1 (driven-side transport stage), and a stopper 571 is provided on the other end of the shaft 57. One end of the shaft 58 is connected to the supporting portion 53 for the third transport stage TS3 (driven-side transport stage), and a stopper 581 is provided on the other end of the shaft 57. A spring 572 is provided on the shaft 57 and stretched between the supporting portion 51 for the first transport stage TS1 and the supporting portion 52 for the second transport stage TS2. Similarly, a spring 582 is provided on the shaft 58 and stretched between the supporting portion 52 for the second transport stage TS2 and the supporting portion 53 for the third transport stage TS3. Mechanical stoppers 501 and 502 that respectively abut against the supporting portion. 51 for the first transport stage TS1 and the supporting portion 53 for the third transport stage TS3 are provided on opposite end portions of the first linear transporter 5.

When the air cylinder 55 is driven so that the rod 55a is extended, the connecting member 56 connected to the rod 55a is moved and the second transport stage TS2 moves together with the connecting member 56. At this time, since the supporting portion 51 for the first transport stage TS1 is connected to the supporting portion. 52 for the second transport stage TS2 through the shaft 57 and the spring 572, the first transport stage TS1 moves with the second transport stage TS2. Also, since the supporting portion 53 for the third transport stage TS3 is connected to the supporting portion 52 for the second transport stage TS2 through the shaft 58 and the spring 582, the third transport stage TS3 also moves with the second transport stage TS2. Thus, by driving with the air cylinder 55, the first transport stage TS1, the second transport stage TS2 and the third transport stage TS3 are linearly reciprocated simultaneously and integrally with each other.

When the first transport stage TS1 is about to move in the direction opposite to the direction of the second transport position TP2 by exceeding the first transport position TP1, the supporting portion 51 for the first transport stage TS1 is stopped by the mechanical stopper 501 and a further movement is absorbed by the spring 572, so that the first transport stage TS1 cannot move beyond the first transport position TP1. Therefore, the first transport stage TS1 is accurately positioned at the first transport position TP1. Similarly, when the third transport stage TS3 is about to move in the direction opposite to the direction of the third transport position TP3 by exceeding the fourth transport position. TP4, the supporting portion 53 for the third transport stage TS3 is stopped by the mechanical stopper 502 and a further movement is absorbed by the spring 582, so that the third transport stage TS3 cannot move beyond the fourth transport position TP4. Therefore, the third transport stage TS3 is accurately positioned at the fourth transport position TP4.

The first linear transporter 5 is provided with an air cylinder 590 for linearly reciprocating the fourth transport stage TS4 in the upper stratum. With the air cylinder 590, the fourth transport stage TS4 is controlled so as to move simultaneously with the transport stages TS1, TS2, and TS3 in the lower stratum and in the direction opposite to the direction in which the transport stages TS1, TS2, and TS3 move. In the present embodiment, the linear transporter 5 is driven with the air cylinders 55 and 590. This drive is not performed exclusively by a particular method. For example, the linear transporter 5 may be motor-driven by using a ball screw.

The second linear transporter 6 is provided with three transport stages TS5, TS6, and TS7 capable of moving linearly and reciprocatingly, and these stages are constructed in two upper and lower strata. That is, the fifth transport stage TS5 and the sixth transport stage TS6 are disposed in the upper stratum, and the seventh transport stage TS7 is disposed in the lower stratum. As a result, the transport stages TS5 and TS6 in the upper stratum and the transport stage TS7 in the lower stratum can move freely without interfering with each other, as can those in the linear transporter 5.

The fifth transport stage TS5 transports a wafer between the fifth transport position TP5 and the sixth transport position TP6, at which the pusher 37 is disposed. (which is a wafer delivery position); the sixth transport stage TS6 transports a wafer between the sixth transport position. TP6 and the seventh transport position. TP7, at which the pusher 38 is disposed. (which is a wafer delivery position); and the seventh transport stage TS7 transports a wafer between the fifth transport position TP5 and the seventh transport position TP7. The second linear transporter 6, whose operation not described in detail, moves the transport stages TS5, TS6, and TS7 and supports a wafer with the same arrangement as that for the linear transporter 5.

The transport stages TS1 to TS7 are identical in construction to each other. The first transport stage TS1 will therefore be described below as a representative of the transport stages TS1 to TS7. FIG. 7 comprises diagrams showing the construction of the first transport stage TS1. FIG. 7a is a top view of the first transport stage TS1, and FIG. 7b is a side view of the first transport stage TS1. As shown in FIG. 7a, the first transport stage TS1 is generally U-shaped. The internal space of the generally U-shaped first transport stage TS1 is formed for passage of the lifter 32 at the time of delivery of a wafer, as described above. The pins 50a and 50b are provided on one of portions opposed to each other in the generally U-shaped stage, and the pins 50c and 50d are provided on the other portion. The pins 50a to 50d are provided so as to project upward along a vertical direction from the first transport stage TS1. In the present embodiment, the pins 50a to 50d are identical in shape to each other.

In the present embodiment, the pins 50b and 50c are provided by being placed side by side along the direction of movement of the first transport stage TS1. Similarly, the pins 50a and 50d are provided by being placed side by side along the direction of movement of the first transport stage TS1. The pins 50a and 50b are provided by being placed side by side along a direction perpendicular to the direction of movement of the first transport stage TS1. Similarly, the pins 50c and 50d are provided by being placed side by side along a direction perpendicular to the direction of movement of the first transport stage TS1. As shown in FIGS. 7a and 7b, wafer W is placed on the pins 50a to 50d inside the pins 50a to 50d.

FIG. 7(c) is an enlarged side view of the pin 50 of the transport stage TS according to one embodiment. As shown in FIG. 7(c), tapered portions 50A and 50B of different slope angles, and each of wafers differing in size (W1, W2) can be supported on the corresponding one of the tapered portions 50A and 50B. Therefore the linear transporter 5 in the thus-arranged embodiment can transport wafers differing in size.

FIG. 7d is an enlarged sectional view of the pin 50c of the first transport stage TS1 according to another embodiment. FIG. 7d shows a section of the pin 50c containing centers of the pin 50c and the pin 50b (center points on a horizontal plane). As shown in FIG. 7d, the pin 50c is fixed on TS1 with a bolt 59c inserted in a bolt hole formed in a central portion of the pin 50c along a vertical direction. This pin 50c has a first slant surface Sic and a second slant surface 52c. The first slant surface 51c is slanted with respect to a horizontal direction. (a direction perpendicular to the vertical direction) and faces upward. The second slant surface 52c is slanted with respect to the horizontal direction and faces downward. The second slant surface 52c is formed above the first slant surface 51c. In the present embodiment, the second slant surface 52c is formed at such a position as to continue to the first slant surface 51c. Also, in the present embodiment, the first slant surface 51c and the second slant surface 52c are formed through the entire circumference perpendicular to the vertical direction. That is, the portion of the pin 50c corresponding to the first slant surface 51c has such a shape that the pin 50c gradually becomes smaller in outside diameter in an upward direction. On the other hand, the portion of the pin 50c corresponding to the second slant surface 52c has such a shape that the pin 50c gradually becomes larger in outside diameter in the upward direction.

In the present embodiment, the first slant surface 51c includes a third slant surface 53c and a fourth slant surface 54c. The fourth slant surface 54c is formed above and continuously with the third slant surface 53c. The fourth slant surface 54c is formed so that its slope angle with respect to the horizontal direction is larger than that of the third slant surface 53c. The first slant surface 51c may include three or more slant surfaces differing in slope angle.

A wafer can be placed on any of the third slant surface 53c and the fourth slant surface 54c of the pin 50c. FIG. 7d shows a state where wafer W1 is placed on the third slant surface 53c and a state where wafer W2 is placed on the fourth slant surface 540 wafer W2 is larger than wafer W1. When the wafer W1 is placed on the third slant surface 53c of the pin 50c, placement of wafer W1 on the third slant surfaces 53a, 53b, and 53d of the pins 50a, 50b, and 50d, not illustrated, is performed. That is, wafer W1 is placed substantially horizontally. Wafer W2 is placed in the same way on the fourth slant surfaces 54c.

Although wafer W1 is placed in the vicinity of an upper end point 57c of the third slant surface 53c in the case shown in FIG. 7d, it can be placed at an arbitrary position on the third slant surface 53c. However, it is desirable to secure as large a wafer W1 deviation margin as possible in order to reduce the occurrence of falls of wafers W1 from the pin 50c. From this viewpoint, it is desirable to place wafer W1 as high as possible. Placement of wafer W1 at the upper end point 57c facilitates regulation of the position of wafer W1. It is desirable to set the positions of the pins 50a to 50d in such a way according to the size of wafer W1. In these respects, the same can be said about wafer W2.

Thus, the third slant surface 53c and the fourth slant surface 54c are provided in the first slant surface 51c to enable placement of two kinds of wafers W1 and W2 differing in size on the first transport stage TS1. That is, one first transport stage TS1 can handle a plurality of wafers differing in size and the device is thus improved in versatility.

In the present embodiment, the upper end point 57c of the third slant surface 53c (the lower end point of the fourth slant surface 54c) is positioned on the wafer placement side relative to an upper end point 56c of the second slant surface 52c along the direction of a straight line passing through the centers of the pins 50c and the pin 50b. This positional relationship between the upper end point 57c and the upper end point 56c is established along the direction of a straight line (hereafter referred to simply as “straight line direction”) passing through the centers of arbitrary two of the pins 50a to 50d. With this arrangement, wafer W1 can be placed on the third slant surface 53c from above while being held in a state of being parallel to the horizontal direction without interfering with the upper end point 56c. As a result, the efficiency of processing relating to transport of wafers can be improved and the mechanism for placing wafers can be simplified.

It is desirable that the position of the upper end point 56c be remoter from the upper end point 57c on the side opposite from the side on which the wafer is placed (hereinafter referred to simply as “opposite side”). For example, it is desirable that the upper end point 56c be positioned on the opposite side relative to the position of a center of the fourth slant surface 54c along the straight line direction. It is more desirable that the upper end point 56c be positioned in a region of the fourth slant surface 54c on the opposite side that is one-third of the fourth slant surface 54c when the fourth slant surface 54c is equally divided into three regions along the straight line direction. With this arrangement, the same effect as that in the case of placement of wafer W1 on the third slant surface 53c can also be expected in the case of placement of wafer W2 on the fourth slant surface 54c.

FIG. 7e shows a state where the occurrence of falls of wafers is reduced by the pins 50a to 50d. FIG. 7e shows sections of the pins 50b and 50c containing the centers of the pin 50c and the pin 50b. In an initial state, the wafer is placed on the third slant surfaces 53b and 53c, as shown as wafer W3 in FIG. 7e. In a case where the wafer is transported by moving the pins 50b and 50c in the direction of the arrow in the figure, i.e., in the direction from the pin 50b toward the pin 50c, if one end of the wafer (pin 50c side) is shifted. upward along the first slant surface 51c by an impact received during transport of the wafer, particularly at the time of stopping, the other end of the wafer (pin 50b side) moves downward along the third slant surface 53b. However, as shown as wafer W4 in FIG. 7e, the one end of the wafer is brought into abutment against the second slant surface 52c formed so as to face downward, so that this end does not further move upward from the point of abutment beyond the second slant surface 52c. Therefore, the other end of wafer W4 is maintained in a state of being placed on the third slant surface 53b. As a result, the occurrence of falls of wafers is reduced. Moreover, since a reduction in speed of transport of wafers for a reduction of the occurrence of falls of wafers is not required, the manufacturing efficiency is not reduced.

FIG. 7f shows the construction of pins 150b and 150c as a comparative example. The pins 150b and 150c have first slant surfaces 151b and 151c, as do the pins 50b and 50c according to the embodiment. The first slant surfaces 151b and 151c respectively have third slant surfaces 153b and 153c and fourth slant surfaces 154b and 154c identical in shape to the third slant surfaces 53b and 53c and the fourth slant surfaces 54b and 54c according to the embodiment. Vertical surfaces 152b and 152c perpendicular to a horizontal direction are formed above the first slant surfaces 151a and 151c. In a case where a wafer is transported by moving the thus-constructed pins 150b and 150c in the direction of the arrow in the figure, when wafer W3 placed on the third slant surfaces 153b and 153c receives an impact during transport of the wafer, particularly at the time of stopping, one end of wafer W3 can be limitlessly moved upward along the vertical surface 152c and, therefore, there is a possibility of the other end falling from the in 150b, as shown as wafer W. With the pins 50a to 50d according to the above-described embodiment, falls of wafers occurring in such a way can he reduced.

### MODIFIED EXAMPLE 1

A vertical surface perpendicular to a horizontal direction may be formed between the first slant surface 51c and the second slant surface 52c. Also in such a case, the same effect as that in the above-described embodiment can be obtained. From the viewpoint of further limiting the range of movement of a wafer, however, the construction according to the above-described embodiment is more desirable.

### MODIFIED EXAMPLE 2

The first slant surface 51c may be formed by only one slope angle. Also in such a case, the same effect of reducing the occurrence of falls of wafers as that in the above-described embodiment can he obtained. In such a case, the second slant surface 52c may be positioned on the side of the lower end point 55c of the first slant surface 51c (see FIG. 7d) opposite from the wafer placement side along the straight line direction, or may be positioned on the side of the position of a center of the first slant surface 51c opposite from the wafer placement side along the straight line direction. In this way, the facility with which a wafer is placed can he improved, as in the above-described embodiment.

### MODIFIED EXAMPLE 3

It is not necessary to form the first slant surface 51c and the second slant surface 52c through the entire circumference of the pin 50c. The first slant surface 51c and the second slant surface 52c may be formed at least through a region where a wafer is placed.

Inverter

Next, the inverter 31 in the first polishing section 3a will be described. The inverter 31 in the first polishing section 3a is disposed in such a position that the hand of the transport robot 22 in the loading/unloading section 2 can reach the inverter 31. The inverter 31 receives a wafer before polishing from the transport robot 22, turns the wafer upside down and delivers the wafer to the lifter 32.

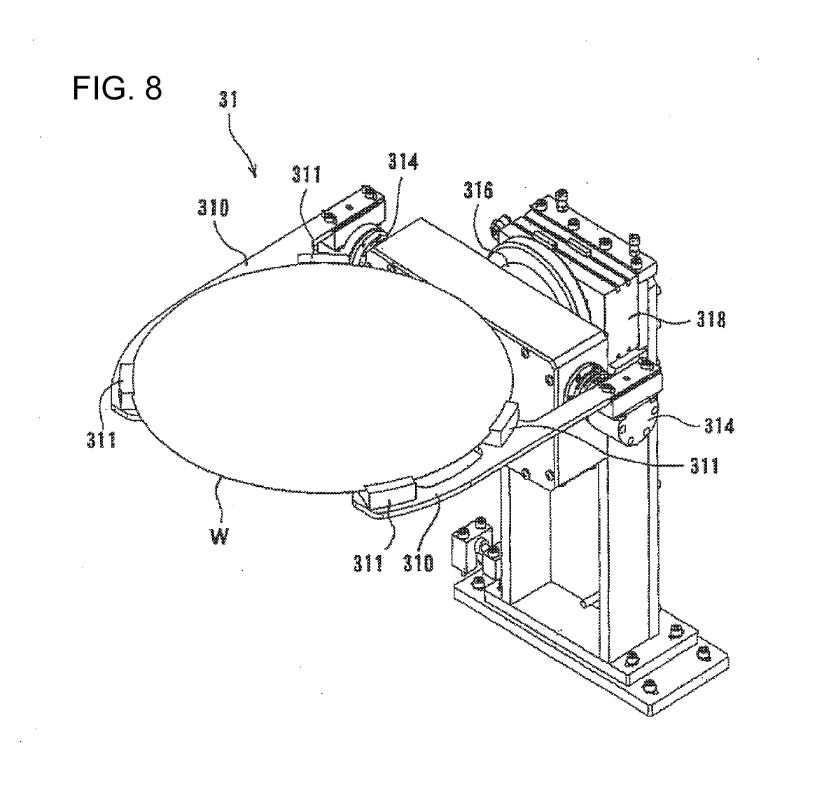

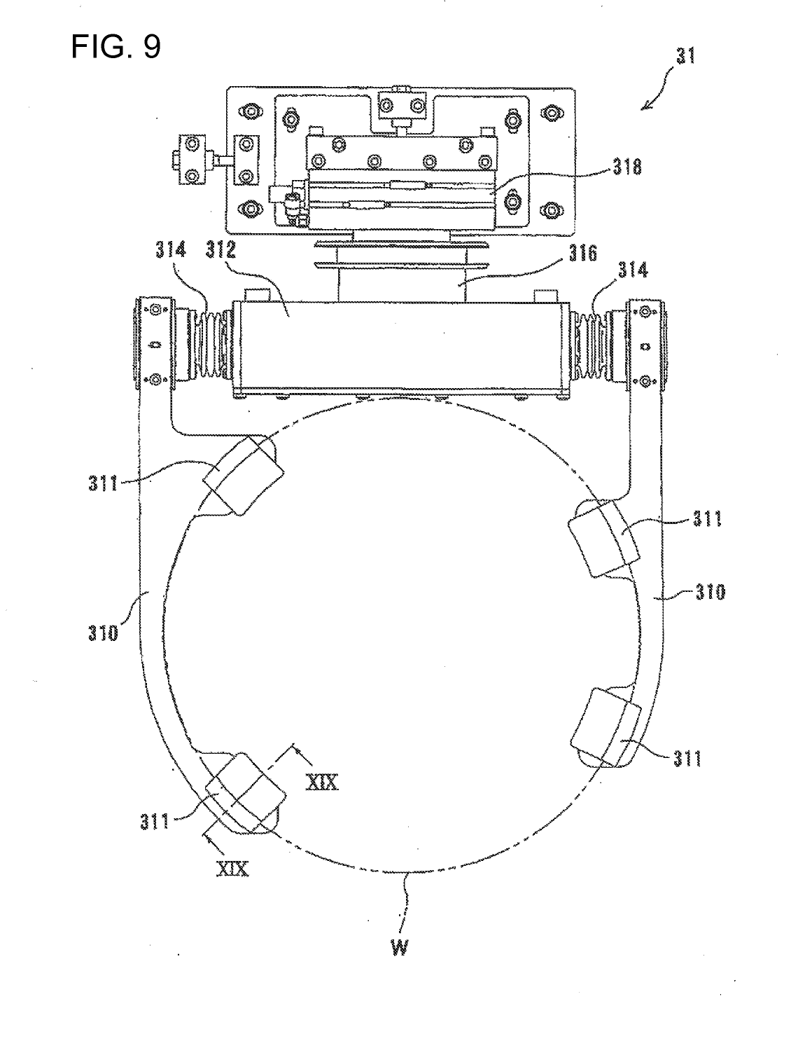

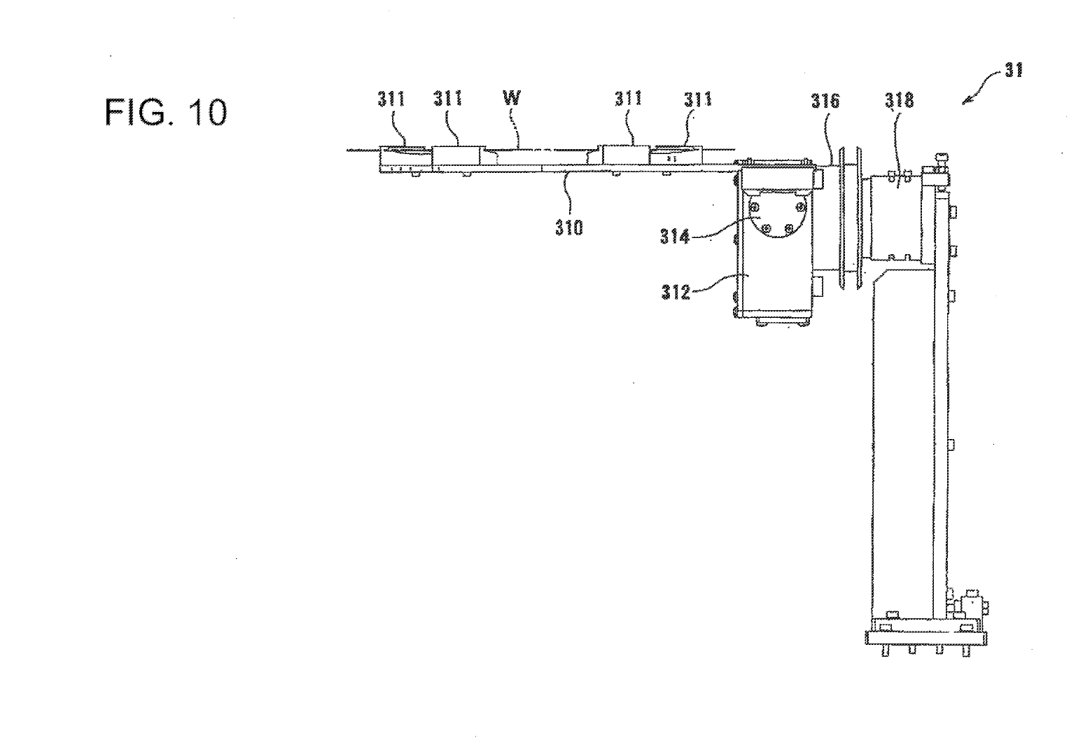

FIG. 8 is a perspective view showing the inverter 31, FIG. 9 is a plan view of FIG. 8, and FIG. 10 is a side view of FIG. 8. As shown in FIGS. 8 to 10, the inverter 31 is provided with a pair of circular-arc holding parts 310 that hold the peripheral edge of wafer W from opposite sides, shafts 314 attached to the holding parts 310, and an opening/closing mechanism 312 that opens and closes the holding parts 310 by moving the shafts 314 in the axial directions of the shafts 314. The pair of holding parts 310 are disposed so as to face each other, with the center of wafer W positioned therebetween. Two pairs of chuck parts 311 that contact outer peripheral portions of wafer W in a line contact manner are respectively provided on pairs of end portions of the holding parts 310. In the description of the present embodiment, an example of the provision of two chuck parts 311 on each holding part 310 is described. However, the present invention is not limited to this. Three or more chuck parts 311 may be provided on each holding part 310,

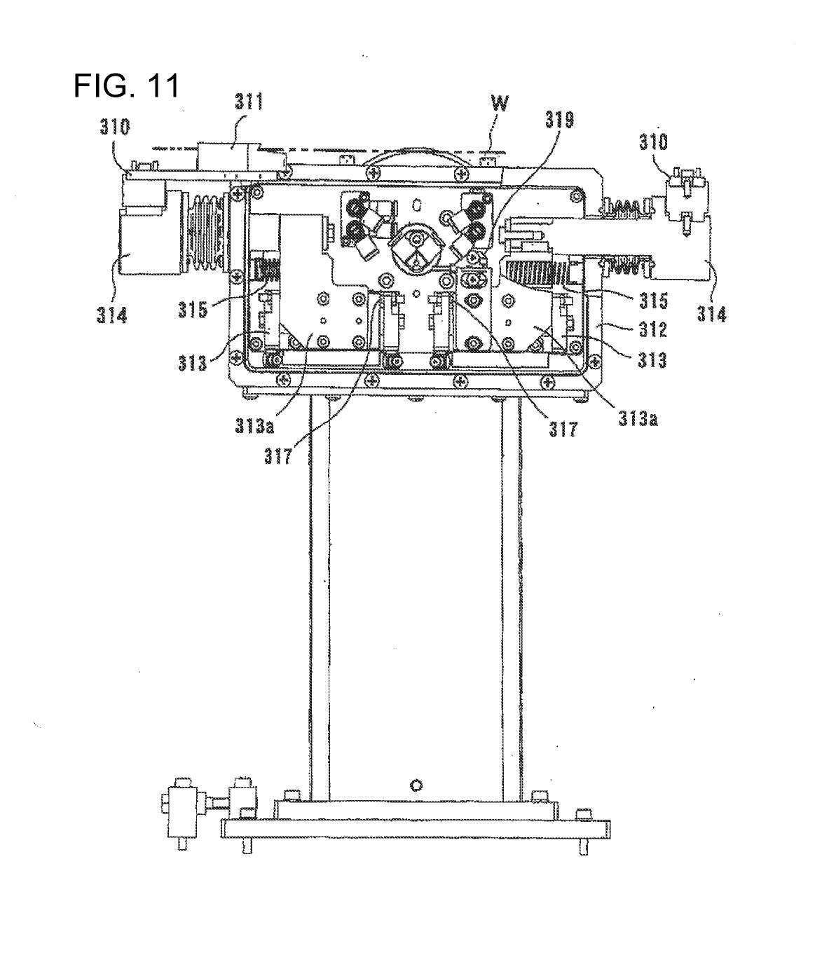

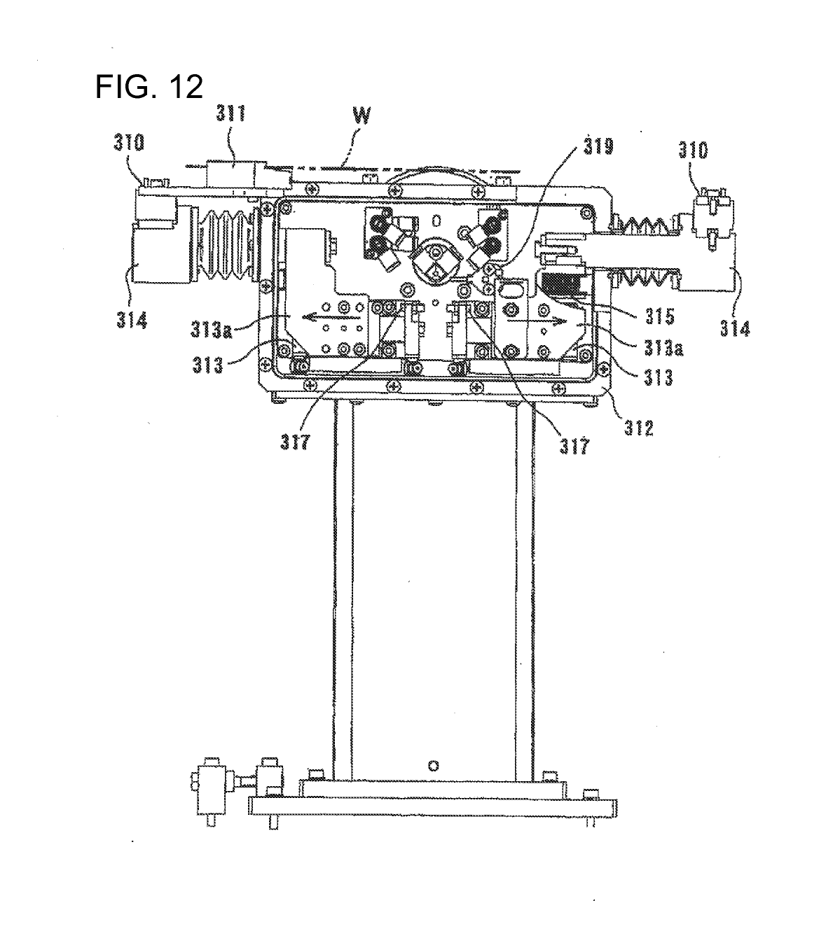

FIG. 11 is a longitudinal sectional view showing the opening/closing mechanism 312 of the inverter 31. As shown in FIG. 11, the opening/closing mechanism 312 is provided with compression springs 315 that urge the shafts 314 and the holding parts 310 in closing directions, and slide-type air cylinders 313 respectively connected to the shafts 314. This opening/closing mechanism 312 moves the holding parts 310 with compression springs 315 in such directions that the holding parts 310 are brought closer to each other, thereby holding wafer W. At this time, movable parts 313a of the air cylinders 313 are brought into abutment against mechanical stoppers 317. Also, the opening/closing mechanism 312 moves the holding parts 310 by driving with the air cylinders 313 in such directions that the holding parts 310 move away from each other, thereby releasing wafer W. FIG. 12 shows the state at the time of this movement.

That is, to hold wafer W, one of the air cylinders 313 is pressurized, while the other air cylinder 313 is closed only by the urging force of the compression spring 315. At this time, only the movable part 313a of the pressurized air cylinders 313 is pressed against the mechanical stopper 317 and fixed at the corresponding position. At this time, the position of the holding part 310 connected to the other air cylinder 313 urged by the compression spring 315 is detected with a sensor 319. In the case of absence of wafer W, the air cylinder 313 not pressurized is at the full stroke position and there is no response from the sensor 319. This is a detection result indicating that no wafer W is held.

As described above, the compression springs 315 are used to hold wafer W and the air cylinders 313 are used to release wafer W, thus enabling preventing wafer W from being damaged by pneumatic pressure in the air cylinders 313.

As shown in FIGS. 8 to 10, a rotary shaft 316 that rotates on an axis perpendicular to the center axis of wafer W is attached to the opening/closing mechanism 312. The rotary shaft 316 is connected to an inverting mechanism 318 and is rotated by the inverting mechanism 318. Accordingly, when the inverting mechanism 318 is driven, the opening/closing mechanism 312 and holding parts 310 are rotated to invert wafer held on the holding parts 310.

FIG. 13 comprises side views of the chuck. 311. FIG. 13(a) shows a state before inversion of semiconductor wafer W adhered to glass substrate G, and. FIG. 13(b) shows a state after inversion. As shown in FIG. 13, the chuck part 311 of the inverter 31 has a slant surface 311a (a lower projecting portion) that gradually becomes higher from the inside of wafer G, W along a diametric direction toward the outside, and a slant surface 311b that gradually becomes higher from the outside of wafer G, W along the diametric direction toward the inside. Wafer G, W is positioned between these slant surfaces 311a and 311b. Referring to FIG. 13, wafer W is bonded on glass substrate G. In the state before inversion shown in FIG. 13(a), wafer W is positioned on the upper side of glass substrate G. In the state after inversion shown in FIG. 13(b), wafer W is positioned on the lower side of glass substrate G. It is desirable to prevent wafer W from contacting any one of the slant surfaces 311a and 311b. Then the slant surfaces 311a and 311b of the chuck 311 are set as described below.

FIG. 14 is a diagram for explaining a method of determining the slope angle θb of slant surface 311b of the chuck 311. FIG. 14 shows a section of the workpiece in which wafer W is bonded on glass substrate G. A straight line tangent to glass substrate G and semiconductor wafer W in the section of wafer G, W is assumed to be L1. The angle between L1 and the glass substrate is assumed to be θ1. A circle with a radius R centered at the point at which L1 is tangent to wafer W is drawn. This radius R is a clearance between the slant surface 311a and wafer W, which is preferably secured as a design value. R is determined by considering an error in positioning when wafer W is bonded on glass substrate G. A straight line tangent to the circle with radius R and glass substrate G is assumed to be L2. The angle between L1 and L2 is assumed to be θ2. The angle formed by L2 and a straight line parallel to the surface of wafer W is assumed to be θ3. Then the slope angle θb of the slant surface 311b is set equal to or larger than θ3 and smaller than 90° (θ3≦θb≦90°). If θb is set in this range, a clearance equal to or larger than the design value R is necessarily formed between the slant surface 311a and wafer W. Since R is determined, by considering an error in positioning when wafer W is bonded on glass substrate G, the slant surface 311a does not contact wafer W even if a positioning error exists when wafer W is bonded on glass substrate G. Determination based on the same way of thinking as that for determination on the slant surface 311a can be made on the slant surface 311a. If the slope angle θb exceeds 90°, wafer W falls from the inverter by not being supported by the slant surface 311a in the state shown in FIG. 13(b). To prevent falling of wafer W from the inverter, therefore, θb is set smaller than 90°.

The same wafer holding structure as that of the inverter 31 in the polishing section 3 can be constructed for the inverter 41 in the cleaning section 4.

Lifter

The lifter 32 in the first polishing section 3a will be described. The lifter 32 in the first polishing section 3a is disposed in such a position that the transport robot 22 and the first linear transporter 5 can access the lifter 32. The lifter 32 functions as a delivery mechanism for delivering a wafer therebetween. That is, the lifter 32 delivers a waver inverted by the inverter 31 to the first transport stage TS1 or the fourth transport stage TS4 of the first linear transporter 5

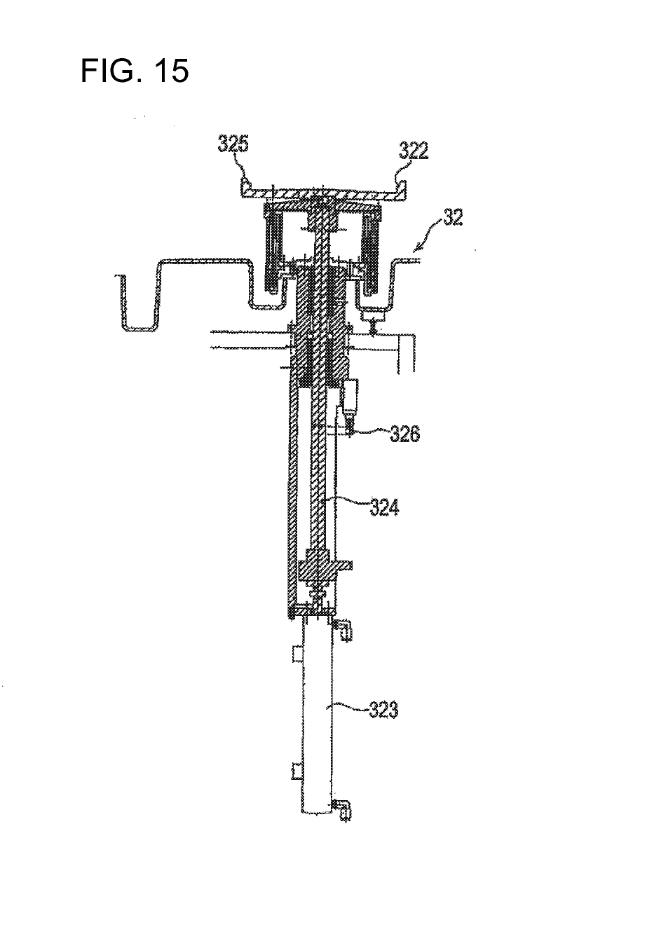

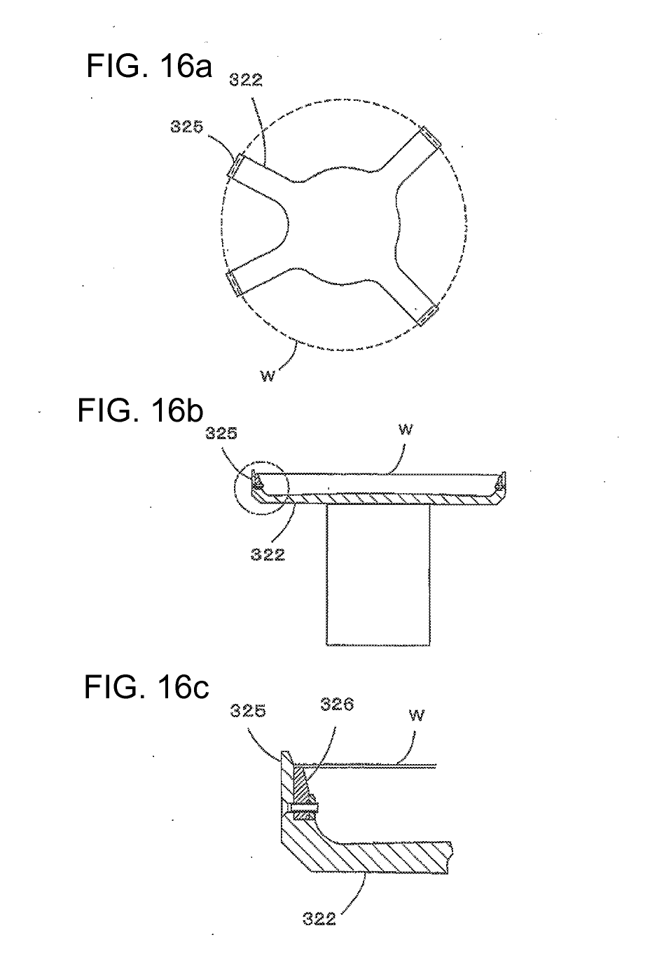

FIG. 15 is a longitudinal sectional view showing the lifter 32. FIG. 16(a) is a top view of a stage 322 of the lifter 32, FIG. 16(b) is a side view of the stage 322, and FIG. 16(c) is an enlarged partial side view of a claw 325 of the stage 322. The lifter 32 is provided with the stage 322 on which a wafer is placed and a cylinder 323 for performing an operation to move the stage 322 upward or downward. The cylinder 323 and the stage 322 are connected by a slidable shaft 324. As shown in FIG. 16(a), the stage 322 is ramified into a plurality of claws 325, which are disposed by being spaced apart from each other by such distances as to be capable of holding even a wafer with an orientation flat placed thereon in such a region that the transport is not influenced. The claws 325 are disposed in such orientations as to be out of phase with the chuck parts of the inverter 31. That is, first wafer edge portions by which the chuck parts 311 hold the wafer and second wafer edge portions held by the claws 325 of the lifter 32 do not coincide with each other. Also, the claws 325 with which wafer delivery operations on the inverter 31 and the first linear transporter 5 are performed have surfaces on which a wafer is placed, and portions of the claws 325 projecting upward beyond these surfaces are tapered so as to absorb an error in transport positioning and to center a wafer when the wafer is placed.

As shown in FIG. 16(c), the claws 325 are provided with wafer supporting members 326. It is preferable that the wafer supporting members 326 be formed of an elastomer material having a hardness of durometer P scale 30 to 50, more preferably 40.

Transport Unit in Cleaning Section

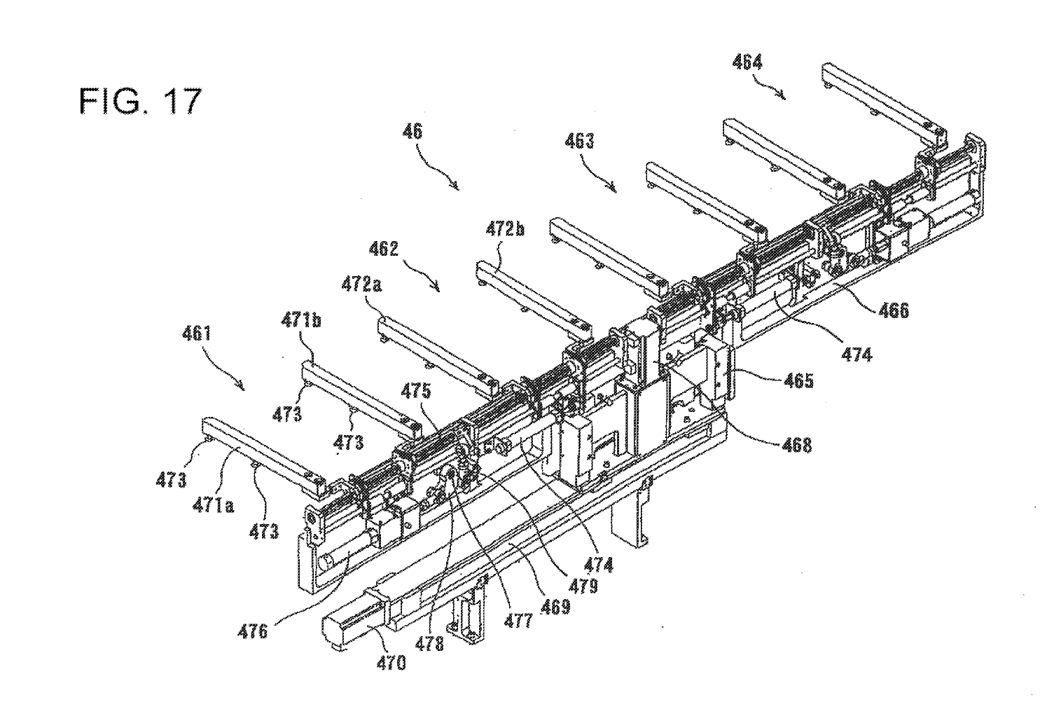

The transport unit 46 in the cleaning section 4 will be described. FIG. 17 is a perspective view showing the transport unit 46. As shown in FIG. 17, the transport unit 46 is provided with four chucking units 461 to 464 as a wafer holding mechanism for detachably holding a wafer in the cleaner. The chucking units 461 to 464 are attached to a guide frame 466 extending in a horizontal direction from a main frame 465. A ball screw (not shown) extending in a vertical direction is attached to the main frame 465. The chucking units 461 to 464 are moved upward and downward by driving with a motor 468 connected to the ball screw. Thus, the motor 468 and the ball screw constitute an upward/downward movement mechanism for moving the chucking units 461 to 464 upward and downward.

A ball screw 469 extending parallel to the row of the cleaners 42 to 45 is also attached to the main frame 465. The main frame 465 and the chucking units 461 to 464 are moved in a horizontal direction by driving with a motor 470 connected to the ball screw 469. Thus, the motor 470 and the ball screw 469 constitute a moving mechanism for moving the chucking units 461 to 464 along the direction of arrangement of the cleaners 42 to 45 (the direction of arrangement of chucking units 461 to 464).

In the present embodiment, the number of chucking units corresponding to the number of cleaners 42 to 45 are used. The structure of the chucking units 461 and 462 and the structure of the chucking units 463 and 464 are basically the same and are symmetrical about the main frame 465. Therefore, description will be made only of the chucking units 461 and 462 below.

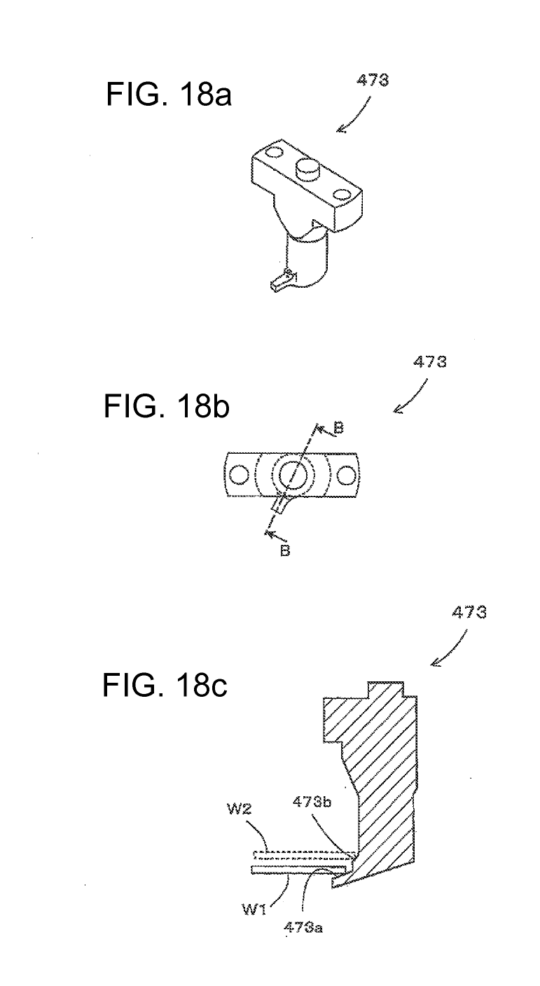

The chucking unit 461 is provided with an openable/closable pair of arms 471a and 471a for holding wafer W, and the chucking unit 462 with a pair of arms 472a and 472b. At least three (four in the present embodiment) chuck contact pieces 473 are provided on the arms in each chucking unit. Peripheral portions of wafer W are chucked and held by the chuck contact pieces 473, thereby enabling the wafer to be transported to the next cleaner. The structure of the chuck contact piece 473 will be described with reference to the drawings. FIG. 18 comprises diagrams showing the chuck contact piece 473. FIG. 18(a) is a perspective view showing the chuck contact piece 473 in a single state before the chuck contact piece 473 is attached. FIG. 18(b) is a top view of the chuck contact piece 473, and FIG. 18(c) is a sectional view taken along line B-B in FIG. 18(b). As shown in FIG. 18(c), slant surfaces 473a and 473b for supporting wafers differing in size are formed on the chuck contact piece 473. Therefore, wafers W differing in size can be transported without adjusting the range of movement of the arms.

As shown in FIG. 17, an air cylinder 474 for opening/closing the arms 471a and 471a of the chucking unit 461 and the arms 472a and 472b of the chucking unit 462 in such directions that the pair of arms are brought closer to each other or moved away from each other is provided on the guide frame 466. A link mechanism or the like for transmitting the motion of the air cylinder 474 to the arms 471a, 471b, 472a, and 472b, not be described in detail, is provided. Accordingly, the end surface of wafer W is chucked between the arms 471a, 471b, 472a, and 472b by closing the arms 471a, 471b, 472a, and 472b with the air cylinder 474. Wafer W can be held in this way. Thus, the air cylinder 474 constitutes an opening/closing mechanism for opening/closing the arms of the chucking units 461 to 464 in such directions that the arms are brought closer to or moved away from each other. Each chucking unit is capable of detecting the presence/absence a wafer by sensing the stroke of the air cylinder. Holding of a wafer may be performed in a vacuum attraction manner. In such a case, wafer presence/absence detection may be performed by measuring the vacuum pressure.

The arms 471a and 471a of the chucking unit 461 and the arms 472a and 472b of the chucking unit 462 are attached to a rotary shaft 475 rotatably mounted on the guide frame 466. Also, an air cylinder 476 for turning the arms 471a, 471b, 472a, and 472b on the rotary shaft 475 is provided on the guide frame 466. A link member 478 capable of turning on a pin 477 is provided on a distal end of a rod of the air cylinder 476. The link member 478 is connected to the rotary shaft 475 by a rod 479. Thus, the air cylinder 476, the link member 478 and the rod 479 constitute a turning mechanism for turning the arms of the chucking units 461 to 464 on the rotary shaft 475.

The embodiments of the present invention have been described. However, the present invention is not limited to the above-described embodiments. For example, the embodiments of the wafer holding mechanisms in the above-described swing transporter, linear transporter, inverter, lifter, cleaning section transport unit, etc., are replaceable with each other if no conflict occurs between them.

For example, the method of determining the slope angle θb of the slant surface 311b of the inverter can be applied in the same way to determination of the slope angles of the tapered portions 120a and 120b of the contact pieces 118 of the swing transporter 7, the slope angles of the tapered portions 50a and 50b of the pins 50 of the linear transporter 5 and the slope angles of the slant portions 473a and 473b of the chucking contact pieces 473 of the transport unit 46. In the case where wafer W is bonded on a glass substrate, determination of the slope angles in the above-described way enables prevention of contact of the holding mechanism with wafer W in the same way as described with respect to the example with the inverter.

What is claimed is:

1. A workpiece transport device for transporting a workpiece having a substrate layer and a layer to be processed on a portion of the substrate layer, the workpiece transport device comprising:
a workpiece holding mechanism arranged to operate so as to hold and release the workpiece, the workpiece holding mechanism having at least one slanted workpiece holding surface on which the substrate layer of the workpiece is held in a state where the layer to be processed is positioned below the substrate layer,
wherein the slanted workpiece holding surface is formed so that a clearance equal to or larger than a predetermined distance R exists between the workpiece holding surface and the layer to be processed of the workpiece when the workpiece is held by the workpiece holding mechanism.

2. The workpiece transport device according to claim 1, wherein the slope angle θb of the slanted workpiece holding surface satisfies θ3≦θb≦90° and θ3=θ1+θ2 where a straight line tangent to the substrate layer and the layer to be processed is assumed to be L1; the angle between the straight line L1 and the substrate layer is assumed to be θ1; when a circle with a radius R centered at the point at which the straight line L1 is tangent to the layer to be processed is drawn, a straight line tangent to the circle with radius R and the substrate layer is assumed to be L2; the angle between the straight line L1 and the straight line L2 is assumed to be θ2; and the angle formed by the straight line L2 and a straight line parallel to a surface of the layer to be processed is assumed to be θ3.

3. The workpiece transport device according to claim 1, wherein the workpiece holding surface has a first surface for holding a workpiece of a first size and a second surface for holding a workpiece of a second size.

4. A workpiece transport device for transporting a workpiece having a substrate layer and a layer to be processed on a portion of the substrate layer, the workpiece transport device comprising:
a workpiece holding mechanism arranged to operate so as to hold and release the workplace, the workplace holding mechanism having at least one workpiece holding surface on which the substrate layer is held,
wherein the workplace holding surface has a first surface for holding a workpiece of a first size and a second surface for holding a workpiece of a second size.

5. A workpiece polishing apparatus comprising the workpiece transport device according to claim 1.

6. A substrate transport device for transporting a substrate, comprising:
a transport stage arranged to be movable in a horizontal direction; and
three or more substrate placement parts provided so as to project upward from the transport stage along a vertical direction, each of the substrate placement parts including:
a first slant surface slanted with respect to the horizontal direction, facing upward and provided for placement of the substrate inside the three or more substrate placement parts; and
a second slant surface slanted with respect to the horizontal direction, facing downward, and formed above the first slant surface.

7. The substrate transport device according to claim 6, wherein the second slant surface is formed in such a position as to continue to the first slant surface.

8. The substrate transport device according to claim 6, wherein the lower end of the first slant surface is positioned on the side on which the substrate is placed relative to the upper end of the second slant surface along the direction of a straight line passing through centers of arbitrary two of the three or more substrate placement parts.

9. The substrate transport device according to claim 6, wherein the first slant surface includes:
a third slant surface having a first slope angle with respect to the horizontal direction; and
a fourth slant surface formed higher than the third slant surface and having a second slope angle larger than the first slope angle.

10. A substrate polishing apparatus comprising the substrate transport device according to claim 6.
